(19) United States
(12) Patent Application Publication
(10) Pub. No.: US 2005/0097740 A1
(43) Pub. Date: May 12, 2005

(54) Color-coded system for installation of spark plug wires on multi-cylinder engines

(76) Inventor: Edward Hawro, Buffalo, NY (US)

Correspondence Address: WALLACE F. NEYERLIN, Esq., 726 Division Avenue, Niagara Falls, NY, 14305, US

(21) Appl. No.: 10/703,895

(22) Filed: Nov. 10, 2003

(51) Int. Cl. H05K 13/00

(52) U.S. Cl. 29/868; 29/854

(57) ABSTRACT

A system of color-coded spark plug wires to facilitate rapid and accurate installation of spark plug wires on multi-cylinder engines; thus facilitating the work of auto repair mechanics and “do-it-yourself” auto repair persons confronted with the problem of insuring that the correct firing order of the spark plugs for the engine is maintained. A preferred embodiment of the color-coding of the spark plugs uses the universal sequence of the colors of the spectrum, i.e., red, orange, yellow, green, blue, indigo and violet. The invention also covers any package of markers for attachment to spark plug wires and containing the spectral rainbow colors; and also any combination of boot color and/or wire color utilizing the sequence of the spectral colors for spark plug wires.

### BACKGROUND OF THE INVENTION

### Field of the Invention and Description of Related Art

When installing spark plug wires on a multi-cylinder engine, care must be taken to install the wire from each spark plug in the engine to the proper post of the distributor. Some wire sets have numbers printed on each spark plug wire to indicate on which cylinder the spark plug wire is to be installed. The distributor cap will then have numbers molded into the cap to correspond to these numbers or it may have a disk with numbered positions that is affixed over the distributor terminals. Although this system is a great improvement over no wire identification at all, it still requires the installer to look closely at each number on the wire and also at the number on the distributor cap. Often the distributor cap is in a location that is not conducive to viewing the numbers on the distributor.

To avoid confusion, many people remove and install one spark plug wire at a time. This is a much slower process than removing all the old wires first and then installing all the new wires.

A system that does not require the reading of individual numbers on wires or of numbers molded into the distributor cap is a better approach.

### BRIEF SUMMARY OF THE INVENTION

This invention relates to a system of color-coded spark plug wires to facilitate rapid and accurate installation of spark plug wires on multi-cylinder engines.

It is essential that spark plug wires be routed from each spark plug to that plug's designated terminal on the distributor. It is an object of this invention to speed up this procedure.

It is another object of this invention to enable the installation of a spark plug wire on a spark plug and on the corresponding distributor terminal for that spark plug very quickly and without looking at small numbers molded into the distributor cap in inconvenient places.

The invention enables faster installation of spark plug wires and/or distributor caps and helps prevent incorrect installation of wires on spark plugs or on distributors.

It is another object of this invention to facilitate the work of auto repair mechanics and “do-it-yourself” auto repairpersons confronted with the problem of insuring that the correct fixing order of the spark plugs for the engine is maintained.

### DETAILED DESCRIPTION OF THE INVENTION

The present invention uses color-coding to identify each individual wire. A preferred embodiment of the invention also uses the universal sequence of the colors of the spectrum, i.e., red, orange, yellow, green, blue, indigo and violet. These colors are often remembered by the mnemonic acronym, ROYGBIV. These seven colors plus either black or white will be sufficient for engines up to eight cylinders.

For engines of 2, 3, 4, 5, 6 or 7 cylinders, the basic spectral colors, i.e., red, orange, yellow, green, blue, indigo and violet will suffice.

For 8 cylinder engines, another color such as black, white, chartreuse, pink or another non-spectral color or a pattern may be used for the boot color. Although the sequence could start with the non-spectral color at position #1, it is preferable to assign this color to position #8. The color then serves as a marker for the end of an octave of cylinders. This extends the color-coding system to engines with more than 8 cylinders. The boot for position #1 is therefore colored red for all engines.

For instance, if the boot for position 8 is black, the boot for position 9 is black with a red sub-color, e.g., a red stripe. Position 10 is black with an orange sub-color. Position 11 is black with a yellow sub-color, and so on until position 15, which is black with an indigo sub-color. Position 16, the end of the next octave, is a white boot. Position 17 is white with red sub-color etc.

Instead of black boots with red, orange, yellow, etc. sub-colors, the boots of the second octave could be red, orange, yellow etc. with a black sub-color to indicate that they are in the second octave of cylinders.

Analogous schemata can be used for coloring the wires as in case #3 described below.

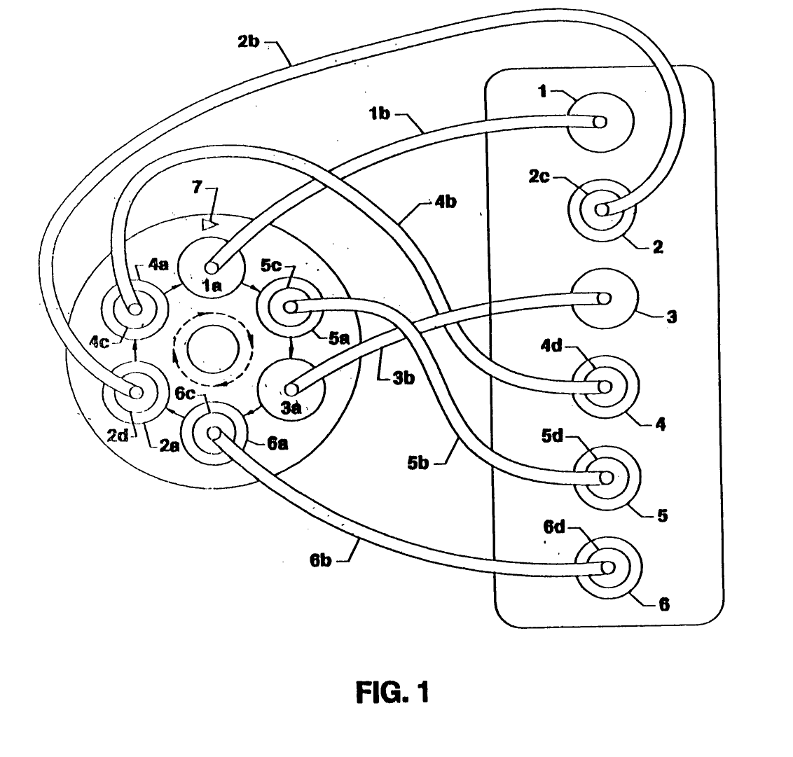

Some V-12 engines have two distributors, one for each bank of 6 cylinders. This case can be treated as two straight six cylinder engines using only the colors red, orange, yellow, green, blue and indigo as in the straight six cylinder engine, illustrated at FIG. 1.

For illustration, a straight six-cylinder engine with firing order of 1, 5, 3, 6, 2, 4 will be considered.

### EXAMPLES

Case #1:

The spark plug boot of each wire is colored to indicate which position in the engine it is to be attached to. Red is the first color, so #1 cylinder's wire has a red boot at the spark plug end. The distributor end of this wire also has a red boot since #1 cylinder is also #1 in the firing order.

The spark plug boot on the wire of #2 cylinder in the engine is orange, the second color of the spectrum. However, the other end of this wire at the distributor has a blue boot since it is #5 in the firing order and hence number 5 distributor position.

Number 3 cylinder's wire has a yellow boot at both ends since number 3 cylinder in the engine is also number 3 cylinder in the firing order.

Number 4 cylinder has a green boot at the spark plug end and an indigo boot at the distributor end since it is 6th in the firing order.

Only the number 1 position and the direction of rotation of the distributor rotor need to be indicated on the distributor cap. For instance, a triangle pointed in the direction of rotation would be molded into the cap at position number 1. This mark might even be made so that touching it with a finger(s) could determine rotation direction without the need for actual visual inspection. Once the red boot is installed correctly at this position, the other colors, i.e., orange, yellow, green, blue and indigo can be quickly installed without looking for position indicators. The sequence of spectral colors provides the correct order. Of course, if desired, one could color each terminal of the distributor with the color of the wire that belongs to it. A stick-on indicator with an adhesive patch could be included with the spark plug wires to indicate position #1 on the distributor and rotation direction.

Case #2:

Instead of, or in addition to, color-coding the spark plug and distributor boots, the insulation of the wires could be color-coded to indicate firing order (distributor position) with numbers printed on them to indicate location in the engine.

Case #3:

The wire insulation could be color-coded to indicate distributor (firing order) position with a sub color to indicate cylinder location. For instance, in the above example, cylinder #1 is solid red since it is #1 in cylinder and distributor position. Likewise cylinder #3 is solid yellow since it is #3 in engine position and also #3 in distributor position.

The wire for distributor position 4 would be green with an indigo sub color, e.g., a stripe, to show 4th in firing order and 6th in engine position. Vice versa, the insulation could be colored to indicate engine position with the sub color used to indicate distributor position.

Case #4:

The wires could be colored to indicate firing order (distributor position) and a marker could be attached to the spark plug end to indicate cylinder position. The marker could be a number, a color, or both. The marker could be the color of the spark plug boot. Vice versa, the wire color can indicate engine position and the distributor boot color or marker can indicate distributor (firing order) position.

Case #5:

The spark plug boots can be colored to indicate engine position with a sub color to indicate firing order position. For instance, a blue boot for spark plug #5 could have an orange ring to indicate that it is #2 in the firing order.

Similarly, the distributor boots are colored to indicate firing order with a sub color to indicate what spark plug position is associated with that firing order position. Thus the #2 distributor boot is orange with a blue ring to indicate that spark plug #5 is at the other end of the wire. The sub color could be integral to the boot material or could a marker, e.g. a ring, attached to the boot.

This method as well as the method described in case #3 allows discerning what is at the other end of the wire when looking at either the engine end or at the distributor end of the wire.

In addition, any package of markers attached to spark plug wires and containing the rainbow colors should be considered a variant of the above methods. Any combination of boot color and/or wire color utilizing the sequence of the spectral colors for spark plug wires should also be considered as a variant of the above methods.

This invention will also be useful when changing spark plugs since it will be very easy to replace the wire on the correct spark plug. This is especially true on V configuration engines where wires on adjacent cylinders are often very close in length and can easily be attached to the wrong cylinder.

FIG. 1 illustrates the foregoing Case #1 Example. In this Figure, which is illustrative of a six-cylinder engine, the spark plugs are identified by the numbers 1, 2, 3, 4, 5 and 6 in the rectangle at the right of the Figure and the Distributor boots are identified as the numeral 1a, 2a, 3a, 4a, 5a and 6a in the circle at the left side of the Figure. Numeral 7 in the circle at the left indicates the number 1 cylinder position and the rotation direction of the six-cylinder engine with a 1, 5, 3, 6, 2, 4 firing order. The colors for the spark plug boots and for the distributor boots in FIG. 1 and for the connection wires between the spark plug boots and the distributor boots follow the preferred embodiment of the invention using the universal sequence of the colors of the spectrum, i.e., red, orange, yellow, green, blue, indigo and violet, which colors are often remembered by the mnemonic acronym, ROYGBIV. The following Table sets forth the respective colors of the spark plug boots, the distributor boots and the various connecting wires referred to in the Table for the six-cylinder engine with the firing order 1, 5, 3, 6, 2, 4 of the engines.

| | | |
|---|---|---|
| 1 | RED SPARK PLUG BOOT | FIRING ORDER 1^{st} |
| 1a | RED DISTRIBUTOR BOOT | |
| 1b | SOLID RED WIRE | |
| 2 | ORANGE SPARK PLUG BOOT | FIRING ORDER 5^{th} |
| 2a | BLUE DISTRIBUTOR BOOT | |
| 2b | BLUE WIRE w/ ORANGE STRIPE | |
| 2c | BLUE DISTRIBUTOR BOOT w/ ORANGE STRIPE | |
| 2d | ORANGE SPARK PLUG BOOT w/ BLUE STRIPE | |
| 3 | YELLOW SPARK PLUG BOOT | FIRING ORDER 3^{rd} |
| 3a | YELLOW DISTRIBUTOR BOOT | |
| 3b | SOLID YELLOW WIRE | |
| 4 | GREEN SPARK PLUG BOOT | FIRING ORDER 6^{th} |
| 4a | INDIGO DISTRIBUTOR BOOT | |
| 4b | INDIGO WIRE w/ GREEN STRIPE | |
| 4c | INDIGO DISTRIBUTOR BOOT w/ GREEN STRIPE | |
| 4d | GREEN SPARK PLUG BOOT w/ INDIGO STRIPE | |
| 5 | BLUE SPARK PLUG BOOT | FIRING ORDER 2^{nd} |
| 5a | ORANGE DISTRIBUTOR BOOT | |
| 5b | ORANGE WIRE w/ BLUE STRIPE | |
| 5c | ORANGE DISTRIBUTOR BOOT w/ BLUE STRIPE | |
| 5d | BLUE SPARK PLUG BOOT w/ ORANGE STRIPE | |
| 6 | INDIGO SPARK PLUG BOOT | FIRING ORDER 4^{th} |
| 6a | GREEN DISTRIBUTOR BOOT | |
| 6b | GREEN WIRE w/ INDIGO STRIPE | |
| 6c | GREEN DISTRIBUTOR BOOT w/ INDIGO STRIPE | |
| 6d | INDIGO SPARK PLUG BOOT w/ GREEN STRIPE | |
| 7 | INDICATES #1 CYLINDER POSITION AND ROTATION DIRECTION | |

It should be mentioned that although the color blue is used for spark plug #5 and indigo for spark plug #6, in practice a lighter shade of blue could be used for #5 and a darker shade of blue could be used for spark plug #6, and not a true indigo which is very dark and could be confused with black.

While the present invention has been described and illustrated in detail, various modifications may be made by those skilled in the art. It is therefore to be understood that the invention is not to be limited to the details of construction described and illustrated and it is intended by the appended claims to cover all modifications which fall within the spirit and scope of the invention.

1. A method of facilitating rapid and accurate installation of spark plug wires on a six-cylinder engine which comprises using color-coding of the spark plug wires, the spark plugs and the distributor caps to insure that the correct firing order of the spark plugs for the engine is maintained, said method including coloring the six spark plug boots with the first six colors of the spectrum, i.e., red, orange, yellow, green, blue, indigo, and coloring the distributor boots with the same colors of the spectrum but in colors corresponding to the firing order of the six-cylinder engine, i.e., the colors red, blue, yellow, indigo, orange and green for an engine where the firing order of the cylinders is 1, 5, 3, 6, 2 and 4.

2. A method according to claim 1 wherein the wire connecting the red spark plug boot to the red distributor boot is a solid red wire, wherein the wire connecting the orange spark plug boot to the blue distributor boot is a blue wire with an orange stripe, wherein the wire connecting the yellow spark plug boot to the yellow distributor is a solid yellow wire, wherein the wire connecting the green spark plug boot to the indigo distributor boot is an indigo wire with a green stripe, wherein the wire connecting the blue spark plug boot to the orange distributor boot is an orange wire with a blue stripe, and wherein the wire connecting the indigo spark plug boot to the green distributor boot is a green wire with an indigo stripe.

3. A method of facilitating rapid and accurate installation of spark plug wires on a twelve-cylinder—two distributor engine, one distributor for each bank of six-cylinders, which comprises using color-coding of the spark plug wires, the spark plugs and the distributor caps to insure that the correct firing order of the spark plugs for the engine is maintained, said method including coloring the six spark plug boots of each bank of six cylinders with the first six colors of the spectrum, i.e., red, orange, yellow, green, blue, indigo, and coloring the distributor boots of each distributor with the same colors of the spectrum but in colors corresponding to the firing order of each of the six-cylinder engines, i.e., the colors red, blue, yellow, indigo, orange and green for the engine where the firing order of the cylinders is 1, 5, 3, 6, 2 and 4 for each bank of six-cylinders.

4. A method according to claim 3 wherein the wire connecting the red spark plug boot to the red distributor boot of each bank of cylinders is a solid red wire, wherein the wire connecting the orange spark plug boot to the blue distributor boot is a blue wire with an orange stripe, wherein the wire connecting the yellow spark plug boot to the yellow distributor is a solid yellow wire, wherein the wire connecting the green spark plug boot to the indigo distributor boot is an indigo wire with a green stripe, wherein the wire connecting the blue spark plug boot to the orange distributor boot is an orange wire with a blue stripe, and wherein the wire connecting the indigo spark plug boot to the green distributor boot is a green wire with an indigo stripe of each bank of 6 cylinders.

5. Any package of markers for attachment to spark plug wires and containing the spectral rainbow colors, i.e., red, orange, yellow, green, blue, indigo and violet.

6. Any combination of boot color and/or wire color utilizing the sequence of the spectral colors for spark plug wires.

7. A method of facilitating rapid and accurate installation of spark plug wires on an eight-cylinder engine which comprises using color-coding of the spark plug wires, the spark plugs and the distributor caps to insure that the correct firing order of the spark plugs for the engine is maintained, said method including coloring the eight spark plug boots with the first seven colors of the spectrum, i.e., red, orange, yellow, green, blue, indigo and violet, and the eighth spark plug boot with a non-spectral color and coloring the distributor boots with the same colors, but in colors corresponding to the firing order of the eight-cylinder engine.

8. A method according to claim 7 wherein the non-spectral coloring of the eighth spark plug boot or the coloring of the eighth distributor boot is selected from the group of black, white, chartreuse, pink or a pattern.

9. A method of facilitating rapid and accurate installation of spark plug wires on a six-cylinder engine which comprises using color-coding of the spark plug wires, the spark plugs and the distributor caps to insure that the correct firing order of the spark plugs for the engine is maintained, said method including coloring the six spark plug boots with the first six colors of the spectrum, i.e., red, orange, yellow, green, blue, indigo, and coloring the distributor boots with the same colors of the spectrum but in colors corresponding to the firing order of the six-cylinder engine
